(19) United States
(12) Patent Application Publication
(10) Pub. No.: US 2015/0301444 A1
(43) Pub. Date: Oct. 22, 2015

(54) SYSTEMS AND METHODS FOR DRY PROCESSING FABRICATION OF BINARY MASKS WITH ARBITRARY SHAPES FOR ULTRA-VIOLET LASER MICROMACHINING

(71) Applicant: INDIAN INSTITUTE OF TECHNOLOGY KANPUR, Uttar Pradesh, Kanpur (IN)

(72) Inventors: Govind Dayal SINGH, Uttar Pradesh, Kanpur (IN); Subramaniam Anantha RAMAKRISHNA, Uttar Pradesh, Kanpur (IN); Janakarajan RAMKUMAR, Uttar Pradesh, Kanpur (IN)

(21) Appl. No.: 14/408,721

(22) PCT Filed: Jun. 17, 2013
(86) PCT No.: PCT/IB13/54943

§ 371 Date: Dec. 17, 2014

(30) Foreign Application Priority Data
Jun. 18, 2012 (IN) 1858/DEL/2012

(51) Int. Cl. G03F 1/76; B01J 19/12

(52) U.S. Cl. CPC G03F 1/76; B01J 19/121

(57) ABSTRACT

A system and method for producing binary dry process laser microfabrication masks is disclosed. A laser is focused on a first mask to produce a mask image, the mask image thereafter being reduced by demagnification optics to provide a reduced image. A target is exposed to the reduced image to create features of reduced size from the original mask. The target may be used to form a binary mask capable of withstanding laser radiation power necessary for direct target micromachining. A binary mask may be used to create other binary masks in an iterative process to provide binary masks with successively smaller features based on the image reduction due to the demagnification optics.

### BACKGROUND

Laser microfabrication masks with micron sized spatial features are used in a number of industrial processes including the fabrication of integrated circuits, MEMS devices, and materials with attractive optical properties. These industrial processes may comprise wet processing and dry processing techniques.

Wet processing techniques use a photoresist material fixed to a target material, in which the photoresist is exposed to an image created by a UV light source such as a UV laser, or other ionizing radiation sources such as e-beam or ion beam directed through the mask. Thereafter, the target and exposed photoresist are processed to provide the features desired. Wet processing derives its name from the use of chemical washes used during the process. In dry processing techniques, the target is exposed directly to the mask image, and the features are formed due to target material ablation or other physico-thermal alterations.

While wet process techniques are common, they suffer from several deficiencies. Multiple steps are required for the process including target preparation, application of the photoresist material, and chemical removal of the undesired resist material. Further, significant chemical waste is produced due to the solvents employed. Dry processes do not suffer from these limitations, but require significantly greater laser power than wet processes in order to bring about direct target modification. Therefore desirable properties for a dry process mask include small feature size, a high damage threshold to laser power, and mechanical stability.

### SUMMARY

In an embodiment, a method of dry process fabrication of a binary laser microfabrication mask may include providing a laser radiation output, providing a first laser microfabrication mask having a first side and a second side, focusing the laser radiation output on the first side of the first laser microfabrication mask causing it to emit a mask image from its second side, providing a first demagnification optics system having a focal length to receive the mask image, in which the demagnification optics system is configured to emit a demagnified image having a demagnification ratio greater than 1, mounting a target in a frame, and exposing the target to the demagnified image, the target having at least a first side and a second side.

In an embodiment, a system for dry process fabrication of a binary laser microfabrication mask may include a laser radiation output, a first laser microfabrication mask having a first side and a second side, in which the first side receives the laser radiation output, and the second side emits a mask image, a first demagnification optics system having a focal length configured to receive the mask image and to emit a demagnified image having a demagnification ratio greater than 1, and a target frame that holds a target.

In yet another embodiment, the binary microfabrication mask may be coated with a metal film using physical vapor deposition, coat sputtering, pulsed laser deposition or chemical vapor deposition methods. In another embodiment, the binary microfabrication mask may further include additional layers such as a wetting layer and a reflective layer.

In still another embodiment, the system may include a means of controlling the position of the target with respect to the demagnified image which may include a mount to hold the polymer target on a movable stage that includes at least one movable stage actuator to move the stage in at least one direction. In another embodiment, the movable stage may be controlled by a computer under control by a user.

### BRIEF DESCRIPTION OF THE DRAWINGS

FIG. 1 illustrates a system for fabricating a binary laser microfabrication mask in accordance with the present disclosure.

FIG. 2a illustrates one embodiment of a binary laser microfabrication mask produced in accordance with the present disclosure.

FIG. 2b illustrates another embodiment of a binary laser microfabrication mask produced in accordance with the present disclosure.

FIG. 3 is a flow chart illustrating a method of producing a binary laser microfabrication mask in accordance with the present disclosure.

### DETAILED DESCRIPTION

Microfabrication techniques may find use in the production of many devices having micron and submicron features, such as integrated circuits, MEMS devices and optical devices with unusual properties, such as photonic devices. Microfabrication methods may include both wet and dry processes. In wet processes, such as photolithography, a laser light beam may be focused on a mask to produce a mask image on a target coated with a photoresist material. In photolithography, after exposure to the image, the photoresist material may be solubilized to leave a blocking layer on the target which may thereafter be subjected to a succession of further steps. The “wet” terminology is used to indicate that solvents may be used in the steps associated with preparing the target for application of the photoresist material, as well as washing the resist material off the target. In dry processes, such as laser micromachining by ablation, the image impinges directly on the target and the laser power is used to ablate or otherwise modify the target material. The “dry” terminology is used to indicate that solvents may not be required for the processing steps.

Wet processes may suffer from a number of disadvantages. Multiple steps may be required for the process including target preparation, application of the photoresist material, and chemical removal of the undesired resist material. In addition to the amount of time required for each step, significant chemical waste may be produced due to the solvents employed. In addition, chemical solvents may be expensive (particularly if a high purity grade is required) and the left-over or unused solvents must be stored or disposed of in an environmentally safe manner.

Dry processing has several advantages over wet processing. Fewer steps are required for dry fabrication than for wet fabrication, and therefore the dry processes may have a faster product throughput time. Additionally, the dry fabrication processes may not require the use of the cleaning and stripping solvents that may be necessary for the wet processes.

A disadvantage of the dry process techniques is that the power required for direct image modification of target material may be much greater than that required for photoresist exposure. Photolithography may be carried out by a continuous wave source of even a few milliwatts, the process being dictated by the total exposure of the work piece to the radiation.

Dry process machining, however, may require laser pulses providing an exposure on the order of MW/cm², which may be outside the working range of continuous wave sources. Consequently, a dry process mask for patterning a target material during microfabrication desirably can be able to withstand the increased laser power. Since the object of microfabrication is to produce target material with micron and sub-micron features, a dry process mask can combine resistance to laser power degradation along with small feature size.

Table 1 compares a variety of parameters associated with the different methods of producing dry process masks.

TABLE 1

| | | | | | Electric |
|---|---|---|---|---|---|
| Methods | | Photo- | E-beam | Electro-chemical | discharge |
| Parameters | This Disclosure | lithography | lithography | machining | machining |
| Feature size | 0.5-100 | 0.3-100 | 0.05-100 | 30-100 | 50-100 |
| (microns) | | | | | |
| Features | Good | Good | Very good | Moderate | Poor |
| with sharp | | | | | |
| angles | | | | | |
| Coverage | Few cm² | Few cm² | 100 m × 100 m | Few cm² | Few cm² |
| area size | | | | | |
| Dry/wet | Dry | Wet (organic | Wet (organic | Wet (acids/bases) | Dry/wet |
| processing | | solvents) | solvents) | | |
| Processing/ | Low | High | High | Very Low | Very Low |
| material cost | | | | | |
| Machining | High | High | Low | Very high | Low |
| rate | | | | | |
| Minimum | (2) Laser | (5) photo- | (5) electron-resist | (1) conducting | (1) conducting |
| number of | machining and | resist coating, | coating, exposure, | samples only | substrates only |
| steps | metallization | exposure, | development, | possible | possible |
| required | | development, | metallization, lift- | | |
| | | metallization, | off | | |
| | | lift-off | | | |

Photolithography, E-beam lithography and electro-chemical machining are all wet processes, which therefore suffer from the limitations of such processes as disclosed above. Electric discharge machining can only be performed on electrically conducting substrates or targets. Methods disclosed herein are dry processes that can be used with a variety of materials, and therefore may not suffer from the limitations presented by the alternative methods. In addition to being economical, having a high machining rate, and the ability to produce small features with sharp angles, the methods and systems disclosed below have the added advantage of using a system readily available in facilities that have equipment for performing the laser micromachining steps.

It may be appreciated that a mask produced by the method and system disclosed below may be used for a variety of microfabrication techniques, including but not limited to photolithography, direct laser writing, e-beam lithography, and ion beam lithography. While the reflectivity and resistance to thermal degradation of such masks may preferentially suggest their use with direct laser microfabrication techniques, it may be appreciated that techniques requiring lower laser power may similarly benefit from the use of such masks.

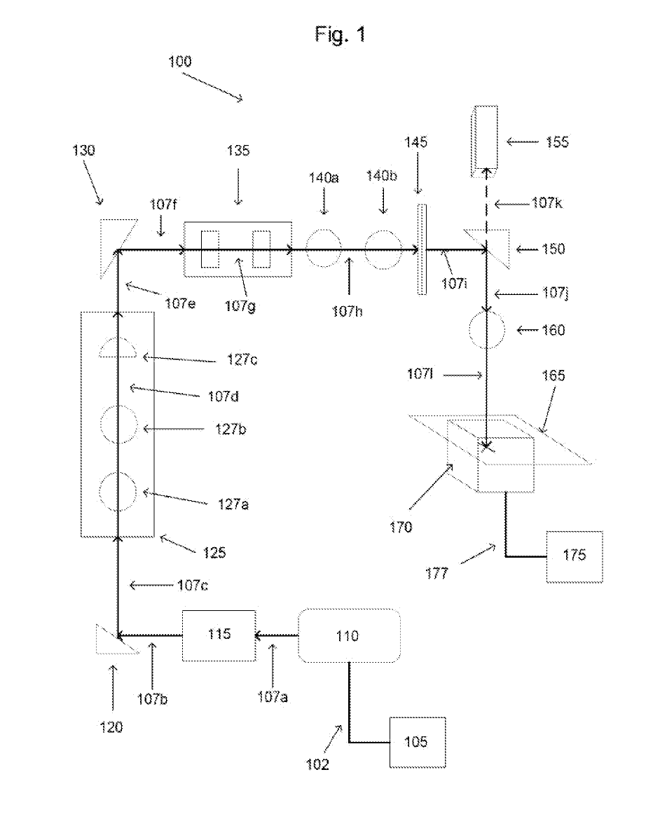

FIG. 1 illustrates one embodiment of a mask microfabrication system 100 having a laser 110, a variety of optical elements, such as 115-140a,b, in the beam path between the laser 110 and the first microfabrication mask 145, demagnification optics 160 located between the first mask 145, and a target 165. The target 165 can be a polymer target, a metallic target or both. The target 165 may be mounted on a movable stage 170, either directly or incorporated in a frame for stabilization. Both laser 110 and movable stage 170 may be controlled by computerized devices, such as a laser radiation output controller 105 to control the output radiation of the laser 110 and a computer 175 to control actuators associated with the movable stage 170. In an embodiment, the functions associated with controllers 105 and 170 may be performed by a single control device.

Laser 110 may comprise any laser used for microfabrication processes. Non-limiting examples of such lasers include a variety of excimer lasers, such as ArF, KrF, XeBr, XeCl, XeF, KrCl, and F₂, as well as non-excimer Nd:YAG, N₂ gas, and HeCd lasers. Depending on the laser used, the laser radiation output may lie within a radiation band of about 150 nm to about 1200 nm. Table 2 provides examples of radiation wavelengths associated with some excimer lasers.

TABLE 2

| | Wavelength |
|---|---|
| Laser Type | (nm) |
| ArF | 193 |
| KrF | 248 |
| XeBr | 282 |
| XeCl | 308 |
| XeF | 351 |
| KrCl | 222 |
| F2 | 157 |
| Nd:YAG | 266 and 354 |
| (4^{th} and 3^{rd} harmonic) | |
| HeCd | 325 and 442 |
| N₂ gas | 337 |

Laser controller 105 may control a variety of laser output parameters via laser control lines 102. For example, the laser output may be pulsed, continuous, or a combination of pulsed and continuous beams. In a non-limiting example, the irradiance of the laser output in continuous mode may be less than or equal to 10 W/cm². In another non-limiting example, the laser output in pulsed mode may have a pulse energy fluence less than or equal to 25 mJ/cm². In an additional embodiment, the laser pulses may have a pulse width from about 1 ps to about 1 μs. The pulse width may be fixed for the duration of a particular machining process or may be dynamically varied according to process parameters. For example, pulse shaping may be useful for clean ablation of target features depending on the target material and feature size. In another embodiment, the pulse width may be fixed at a specific width, such as at about 20 ns. The pulse frequency may also be fixed or dynamically adjusted during machining. In one embodiment, the pulse frequencies may be about 1 Hz to about 50 Hz. In another embodiment, the pulse frequency may be about 10 Hz. Pulse frequency may be chosen to optimize the depth and quality of a cut into the target material based on material composition, laser power, and laser wavelength.

The laser radiation output can travel an optical path such as the one illustrated in FIG. 1 by beam path 107a-1. Beam path 107a is a path from the laser output to attenuator 115 which may be used to reduce the beam power as required by the material of target 165. The output of attenuator 115 may be further directed through a series of focusing optical elements 127a-c of focusing optics system 125, along beam path 107d. The focusing elements 127a-c may include any of a variety or combination of elements, including but not limited to cylindrical lenses, spherical lenses, doublet lenses, triplet lenses, synthetic fused silica lenses and lenses with optical coatings, such as anti-reflective coatings. In one example, the focusing optics may comprise a group of two cylindrical lenses and a spherical lens. In one embodiment, the laser light output from the focusing optics may then be directed through a homogenizer 135 along beam path 107g to provide a uniform intensity beam to illuminate one side of the first microfabrication mask 145. In one embodiment illustrated in FIG. 1, the output beam from attenuator 115 may pass through additional optical elements such as right angle prisms 120 and 130 along beam paths 107b-c, and 107e-f. Such right angle prisms may be used to maintain the required optical path length within a reasonably sized footprint for a manufacturing facility. Additional optical elements also may include field lenses 140a,b coupled by beam path 107h.

The first microfabrication mask 145 includes features that will be imaged on the target 165. The first microfabrication mask may be fabricated from any of a number of materials or combination of materials, including metal sheets, polymer films, or metalized polymer films. Non-limiting examples of metallic sheets include stainless steel, chromium, aluminum or copper, although other malleable metals may also be used. In one embodiment, the metal sheets may have a thickness of about 15 μm to about 1 mm. In another embodiment, the metal sheet thickness may be from about 100 μm to about 150 μm. The metal sheets may be composed of a single metal. Alternately, the metal sheets may comprise layered metals or metals with polymer or metallic coatings. Polymer films may include, without limitation, polyimide, polythene, polyethylene terephthalate and polytetrafluoroethylene. The first microfabrication mask may be fabricated by a number of methods. Some non-limiting methods for manufacturing the first mask may include CNC milling, electrical discharge machining, electro-chemical machining, laser microfabrication, laser etching, electronic beam machining, ion beam machining and plasma beam machining. The first microfabrication mask may also be fabricated by direct laser etching that uses demagnifying optics to create a mask with reduced features from another mask.

As disclosed above, the output radiation from laser 110 can be focused on the upstream side of the first mask 145. On illumination, the features machined in the mask produce an image projected from the downstream side of the mask. The image may then be projected through demagnification optics 160 onto the target 165. In one embodiment, the image from mask 145 may pass directly to the demagnification optics. In another embodiment, the image may be directed along optical path 107i to a dichroic mirror/beam splitter 150. One image from the dichroic mirror may be directed along beam path 107k to a camera 155—comprising, for example, a CCD camera with a phosphor screen—to record and/or analyze the image. The camera 155 may be positioned at an angle with respect to the mirror in order to obtain a useful image. In one non-limiting embodiment, the image data output produced by the camera may be used to program the laser output controller. In an alternative embodiment, the CCD output image may be used to control the position of a movable stage (see below) on which the target is affixed. A second image from the dichroic mirror 150 may be directed along beam path 107j to the demagnification optics 160.

Demagnification optics 160 may comprise a number of optical elements. Some non-limiting examples include spherical lenses, Fresnel lenses, diffractive optics systems, doublet lenses, triplet lenses, synthetic fused silica lenses and coated lenses. Spherical lenses may further include corrections for spherical aberrations, coma and astigmatism. Lens coatings may include anti-reflective coatings among others. The demagnification optics may be used to project a reduced image of mask 145 onto the target 165 based on the focal length of the demagnification optics.

One metric to measure the amount of image reduction due to the demagnification optics is the demagnification ratio. The demagnification ratio is the ratio of the object distance divided by the image distance. The object distance is the optical distance from the first microfabrication mask 145 to the demagnifying optics 160 (e.g. a distance measured in FIG. 1 as the length of beam path 107i+beam path 107j). The image distance is the optical distance from the demagnifying optics 160 to the target 165 (e.g. the distance of beam path 1071). A demagnification ratio greater than 1 indicates that the image on the target has smaller features than those on the first micromachining mask. In a non-limiting example, the demagnification ratio may be about 2 to about 25. In another non-limiting example, the demagnification ratio may be about 10. Specific examples of the demagnification ratio include about 2, about 5, about 10, about 15, about 20, about 25, and ranges between any two of these values.

The use of demagnification optics provides a method to produce masks with small feature size by means of an iterative approach. As an example, the first microfabrication mask may be formed using CNC drilling techniques on thin aluminum to produce a first mask with 2 mm features. Using the demagnification process with a demagnification ratio of 10 would result in a target mask having 200 μm features. The target mask may then be substituted for the first mask, and may be used in a second iteration to produce a mask having 20 μm features. In this manner, masks with from about 2 μm to about 500 μm features, and even sub-micron sized features, may be fabricated using the same equipment.

Although FIG. 1 illustrates an embodiment that incorporates a variety of optical elements configured in a specific order, it may be appreciated that other embodiments may include alternative and/or additional optical elements such as slits, collimators, and shutters. Further, alternative embodiments may lack certain of the optical elements illustrated in FIG. 1, or distribute the elements in a different order along the optical beam path. It should be understood that all such variations in optical elements and arrangements may be contemplated by this disclosure.

The image from the demagnification optics 160 may be projected along beam path 1071 onto a target 165. The target may comprise any suitable material capable of laser machining. Non-limiting examples of such material may include polyimide, polythene, polytetrafluoroethylene, polyethylene terephthalate, aluminum, copper, stainless steel or combinations thereof. In one embodiment, the target may have a thickness of about 5 μm to about 1 mm. In another embodiment, the thickness may be from about 25 μm to about 100 μm The target will require sufficient exposure time to the laser induced mask image to produce the necessary features. The features may be introduced into the target by any one or more of photochemical modification, ablation, physiothermal modification and any other laser induced mechanisms. The laser output controller may be programmed in any number of ways to provide sufficient exposure time to the laser radiation. In some embodiments, the exposure time may be a fixed period of time. In another embodiment, the exposure time may be based on the material composition of the target or its thickness. In another embodiment, exposure time may be based on the size of the mask features. In yet another embodiment, the exposure time may be based on the output power of the laser. In still another embodiment, the exposure time may be based at least in part on the intensity of an image obtained by camera 155.

In order to stabilize the target during machining, the target may be fixed within a frame that is mounted on a movable stage 170. Alternatively, the target may be fixed onto the stage without the use of a frame. The stage motion may be controlled in any one or more of an “x”, a “y”, and a “z” direction. One or more actuators may be provided to move the stage. As non-limiting examples, the actuators may comprise any one or more of a linear motor, a piezoelectric actuator, a pneumatic actuator or a hydraulic actuator. A combination of actuators may move the target horizontally to provide multiple areas that may be sequentially exposed to the first target image, thereby creating a target of repeating features. In addition, the stage may be moved vertically to focus the demagnified image on the target surface. The actuators may be controlled directly by a computer controller 175 through a user interface or via appropriate data and power connections 177. The computer controller 175 may also have a user interface to permit a user to program the motion of the actuators.

After the target has been exposed to the first mask image and the image has been machined into it, the target may then be metallized to form at least one metal coating on at least one side of the target. The metallization may be performed on targets that are polymer targets, metallic targets, or both. Where the target is a metallic target, the metal coating on the target may not be necessary, but can still be coated on the target, for example, to impart structural rigidity or improve reflectiveness. The target may be metalized by means of a coating system including, but not limited to, physical vapor deposition, coat sputtering, pulsed laser deposition, chemical vapor deposition, or other similar techniques used to affix a metallic film coat onto the machined target, resulting in a binary microfabrication mask. Non-limiting examples of metals that may be used to coat the target include silver, aluminum, nickel, stainless steel, invar, copper, and chromium.

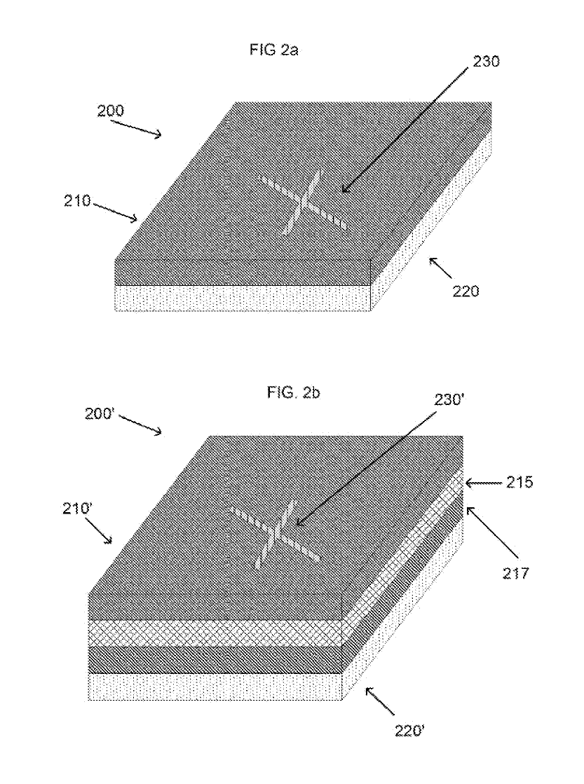

FIG. 2a illustrates one embodiment of the binary mask 200 fabricated according to the system disclosed above. The target 210 is illustrated having an ablated region 230, the material having been removed from the target due to exposure to the laser image. After the coating process, a metalized film 220 is bonded to one side of the target. It may be understood that the binary mask produced by the disclosed system may incorporate one or multiple metallization layers. FIG. 2b illustrates another embodiment of a binary mask 200′ having multiple metalized layers. In the embodiment of FIG. 2b, the original target 210′, having etched or formed features 230′, is further coated with a wetting layer 215 and a reflective layer 217 in addition to the metallized film 220′. The multiple layers may find use in an embodiment in which the metallized film 220′ material may be chosen to impart structural rigidity to the binary mask, and to which a separate reflective layer 217 with high reflectivity properties is added. Depending on the composition of the material in the reflective layer 217, a wetting layer 215 may be required to ensure the reflective layer 217 is properly fixed onto the target 210′. Alternatively, the wetting layer 215 may be used to help affix the metallization layer 220′ to the reflective layer. Non-limiting examples of material for a reflective layer may include aluminum and silver, while non-limiting examples of materials for a wetting layer may also include chromium and titanium. It may be appreciated that although FIG. 2b illustrates all the metalizing layers on a single side of the target, the multiple metal layers may be applied to either side or both sides of the target in any order. Additional polymer or metal layers may also be included in the mask.

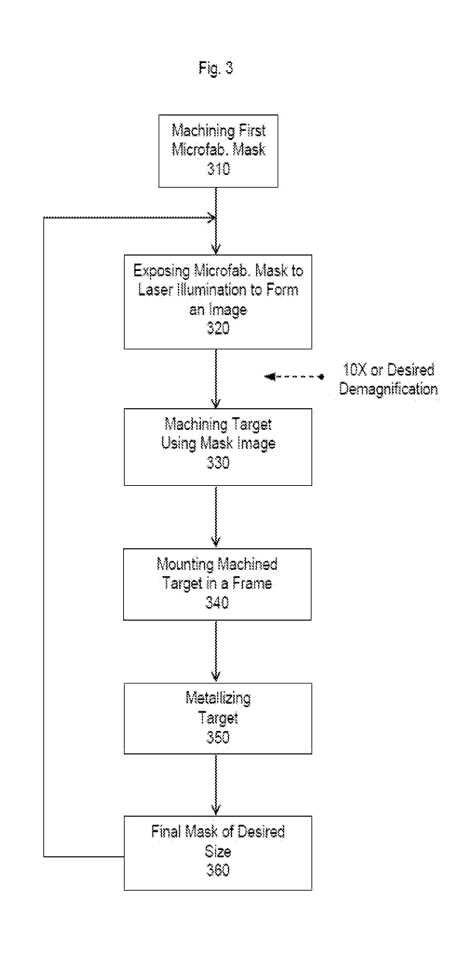

FIG. 3 is a flow chart of an embodiment of a method for using the system disclosed above in FIG. 1 for the fabrication of a binary dry process microfabrication mask. The first microfabrication mask may be fabricated 310 from any of a number of materials or combination of materials, as disclosed above, including as non-limiting examples, metallic foils (such as stainless steel, aluminum, or copper), polymers (such as polyimide, polythene, polyethylene terephthalate or polytetrafluoroethylene), or layered materials comprising both metals and polymers. In one embodiment, the microfabrication mask may be fabricated from a metal sheet or foil having a thickness from about 5 μm to about 1 mm. The first microfabrication mask may be fabricated by a number of methods, including CNC milling, although alternative methods, such as those disclosed above, may be used as well. The first microfabrication mask may also be fabricated by direct laser etching that uses demagnifying optics to create a mask with reduced features from another mask.

The first mask may be exposed to laser illumination 320 on its upstream face to produce an image emitted by its downstream face. As disclosed above, the laser may comprise any of a number of lasers which may provide illumination with wavelengths, for example, of about 150 nm to about 1200 nm, as illustrated in Table 2, above. The laser output may be controlled by a controller capable of varying the laser output in terms of output power and pulse duration and/or frequency; the laser output may also be continuous, pulsed, or mixed continuous and pulsed. Continuous laser irradiance may be less than or equal to about 10 W/cm². Pulsed laser fluence may be less than or equal to about 25 mJ/cm². Laser pulses may have a width of about 1 ps to about 1 μs. The laser radiation output may travel an optical path from the laser to the first microfabrication mask through a series of intervening optical elements, including without limitation, lenses, attenuators and homogenizers, as disclosed above. The image emitted by the downstream face of the first microfabrication mask may be focused on a substrate or target using, for example, demagnification optics, as disclosed above. In one embodiment, the demagnification ratio of the image may be about 2 to about 25. In another embodiment, the image may be presented to a dichroic mirror or beam splitter that can provide an image to a camera in addition to providing the image to the demagnification optics and the target.

The target may be mounted on a movable stage prior to machining. The movable stage may comprise one or multiple actuators, as described above, to move the stage, and thus the target, with respect to the demagnified image. In one non-limiting example, the stage may move horizontally to expose successive areas of the target to the beam, thereby creating a number of repeated features on the target mask. Thus, the target may have one area exposed to the demagnified image for a period of time, the demagnified image may be disabled while the stage moves the target to another position, and then the new target area may be exposed to the demagnified image. In another non-limiting example, the stage may move in a vertical direction to improve image focusing on the target. The camera output from the image formed on the dichroic mirror may be used to provide input to control this motion. The actuators on the movable stage may be controlled by at least one controller. In one embodiment, the controller may include a computer programmed with specific control functions for automated motion control. In another embodiment, the controller may include a user interface, such as a joystick, permitting direct human control of the actuators. In another embodiment, the controller may include a computer having interfaces for a user to program the motion of the stage. In addition, the controller may include functions to control the actuators according to other parameters, such as laser output power or image information obtained from the camera.

Exposure of the target to the demagnified image may result in machining the target 330. The target may comprise, as non-limiting examples, polyimide, polythene, polytetrafluoroethylene, polyethylene terephthalate, aluminum, copper, stainless steel or combinations thereof. The machining process may include, without limitation, ablation, photochemical modification and/or physiothermal modification. In an embodiment, the machining process may be controlled according to the laser power, pulse width and/or exposure time of the substrate to the laser. Exposure time of the target to the demagnified image may be based on any number of parameters, including, but not limited to, the target material, density, and/or thickness, the radiation power, or the size of the features being machined into the target. In an alternative embodiment, the exposure time may be a fixed value independent of such parameters.

After the target is machined, it may be mounted in at least one stabilizing frame for further processing 340. It is understood that the target may be placed in such a frame prior to machining in order to stabilize the target for image exposure.

In one non-limiting example, the target after machining may be subjected to a metallization process 350. At least one side of the target may be metallized using processes including, but not limited to, physical vapor deposition, coat sputtering, pulsed laser deposition and chemical vapor deposition. The metallization process may also include the deposition of multiple metal layers, including but not limited to stability enhancing layers, wetting layers and reflective layers. In one non-limiting embodiment, a metal film made of silver, aluminum or chromium may be deposited on the target. In other non-limiting embodiments, a wetting layer may be composed of chromium or titanium, and a reflective film may include aluminum or silver. It is understood that these examples of metal films are only illustrative and that other suitable metals may be used alone or in combination as part of the metallization process.

As indicated in FIG. 3, the resulting binary mask may be used in an iterative manner to create additional masks having reduced feature size. After a few iterations, a final binary dry process mask may be produced 360, having feature sizes of about 0.5 μm to about 500 μm.

### EXAMPLES

### Example 1

### System for Fabricating Binary Masks

A KrF excimer laser capable of producing 750 mJ pulses with a 25 ns pulse width at 248 nm was used to provide the laser output radiation. A homogenizer that included a pair of 8×8 fixed array insect eye lenses was included to create a uniform illumination field of 20 mm×20 mm at an upstream side of a first laser microfabrication mask. The first mask was fabricated having feature sizes from 10 μm to 1 mm. The downstream side of the first mask would emit a mask image of the features. Demagnification optics were chosen to provide a demagnification ratio of 10, and were configured to receive the mask image and to emit a demagnified image on a target. The targets included polymers such as polyimide and polyethylene terephthalate films, and also metals such as aluminum film. The target was placed on a micro-machining 3-axis translator to position the target with respect to the demagnified image. Line widths of 100 μm, 10 μm, and 1 μm were obtained in the target based on feature sizes of 1 mm, 100 μm, and 10 μm, respectively, on the first mask.

Although not pursued in this Example, the target with the machined features may be coated with a metal film such as aluminum, silver, titanium and chromium to form the binary mask. The binary mask can be used as the first mask for a subsequent photoreduction of the features to form another binary mask having smaller feature sizes. By the use of successive photoreduction of the feature size, binary masks may be produced with final features that are three orders of magnitude smaller than available from the use of a single step of photo-micromachining.

### Example 2

### Conformity of Machined Features in the Target

Using the system as described in Example 1, target samples made of polyimide sheets were fabricated. The polyimide sheets had features of lines intersecting at various angles (similar to the pattern shown in FIGS. 2a and 2b), and with various line widths, formed on them. Each polyimide sheet had a length and breadth of 20 mm, and was 300 μm thick. Within each polyimide sheet was an array of 20 squares, each 1 mm×1 mm in size. Residing within each of the squares, are the intersecting lines. Hence, each polyimide sheet had an array of 20 pairs of intersecting lines formed thereon. A total of 9 target samples were fabricated in accordance with the specifications in Table 2. The angles of intersection of the lines formed on the polyimide sheet for each sample was measured from scanned images obtained using optical microscopy. An average of the measured angles for each target sample, and a deviation of the average from the first mask, are shown in Table 2 below.

TABLE 2

| | | | | Average | |
|---|---|---|---|---|---|
| | | | Line | Angle of | |
| | Angle of | Line width | Width | Intersection | |
| Target | Intersection | (first | (polyimide | (polyimide | |
| Sample | (first mask) | mask) | sheet) | sheet) | Deviation |
| 1.1 | 45° | 1 mm | 100 μm | 45.1° | 0.4° |
| 1.2 | 57° | 1 mm | 100 μm | 56.7° | 0.4° |
| 1.3 | 90° | 1 mm | 100 μm | 90.1° | 0.3° |
| 2.1 | 45° | 100 μm | 10 μm | 44.8° | 0.6° |
| 2.2 | 57° | 100 μm | 10 μm | 56.7° | 0.5° |
| 2.3 | 90° | 100 μm | 10 μm | 89.7° | 0.3° |
| 3.1 | 45° | 10 μm | 1 μm | 44.5° | 1.1° |
| 3.2 | 57° | 10 μm | 1 μm | 57.1° | 1.1° |
| 3.3 | 90° | 10 μm | 1 μm | 90.6° | 1.0° |

As can be seen from Table 2, the lines formed on the polyimide sheets of the target samples have almost the same angles of intersection as those of their respective first masks. The variation was only within 1°, demonstrating that the machined features on the targets are conformal to their respective first masks, even for lines with widths of single micrometer thickness (for example, 1 μm).

### Example 3

### Depth to Width Aspect Ratios of Machined Features in the Target

Using the system of Example 1, targets made from various materials and having various thicknesses were machined with hole patterns. A total of 5 target samples were made in accordance with the specifications in Table 3 below. The diameters and depths of the holes formed on the target samples were measured using optical microscopy and atomic force microscopy. The measured hole diameter for each target sample, and the depth (thickness of the material) to width aspect ratio, are shown in Table 3 below.

TABLE 3

| | Hole | Sheet | Machined | Depth to |
|---|---|---|---|---|
| Material of | Diameter | Thickness | Hole Diameter | Width |
| Target | (first mask) | (target) | (target) | Aspect Ratio |
| Aluminum | 30 μm | 15 μm | 3 μm | 5 |
| Polyimide | 30 μm | 30 μm | 3 μm | 10 |
| Polyethylene | 30 μm | 50 μm | 3 μm | 17 |
| Terephthalate | | | | |
| Polyethylene | 30 μm | 90 μm | 4 μm | 23 |
| Terephthalate | | | | |
| Polyethylene | 30 μm | 100 μm | 4 μm | 25 |
| Terephthalate | | | | |

It can be seen from Table 3 that the diameters of the holes formed on the target samples had generally conformed to those of the first masks. The diameters of the holes formed in the target samples were about 10 times smaller than those of the first masks, which was consistent with the demagnification ratio of 10 configured in the system. For the target samples that have larger thicknesses (for example, 90 μm or greater), the holes that were formed were only slightly broadened (for example, 4 μm). Hence, it is possible to machine single micrometer sized features with large depth to width aspect ratios on a target using the system of Example 1.

### Example 4

### Length to Width Aspect Ratios of Machined Features in the Target

Using the system of Example 1, a target sample made from polyimide and having a thickness of 30 μm was machined with arrays of linear through-slots. The target sample was supported on a glass substrate. The first mask that was used had a through-slot measuring 20 mm long and 100 μm wide. The system was configured with a demagnification ratio of 10. To form the array of through-slots on the target sample, the micro-machining translator was configured to re-position the target lengthwise after each slot was formed. The length and width of the through-slots formed on the target sample were measured using atomic force microscopy. The through-slots that were formed on the target sample were 2 mm long and 10 μm wide each, which conformed with the demagnified through-slot pattern in the first mask. Hence, it is possible to machine single micrometer sized features having large length to width aspect ratios and without distortion on a target using the system of Example 1.

### Example 5

### Uniformity in Large Scale Arrays of Machined Features in the Target

Using the system of Example 1, a large scale array of 2 μm holes with a period of 4 μm was machined on a target sample made from polyimide sheet. Another array of 1 μm diameter holes with a period of 2 μm was machined on another target sample made from polyimide sheet. Each of the two arrays occupied an area of 1 mm×1 mm on the polyimide sheet. The polyimide sheets in both target samples were 30 μm thick and were supported on a glass substrate. The first masks that were used in the system had holes of diameters 20 μm and 10 μm, to form the holes of diameters 2 μm and 1 μm, respectively, on the two target samples. The system was configured with a demagnification ratio of 10. To form the array of holes on the target sample, the micro-machining translator was configured to re-position the target sample along the x- and y-axes after each hole was formed, and the processes of repositioning and forming the holes were repeated until the array was completed for each target sample. The target samples were scanned using optical microscopy and atomic force microscopy to observe uniformity of the arrays formed, and morphology of the holes formed. It was observed that both target samples exhibited uniformity in the pattern of holes formed over the entire 1 mm×1 mm area, that is, the holes were uniform in size, period, and depth. The scans also shows almost identical patterning of holes over different machined areas. Hence, it is possible to machine uniform arrays of single micrometer sized features over large areas using the system of Example 1.

### Example 6

### Method of Fabricating Binary Masks with Serifs

Serifs and notches may be incorporated into microfabrication masks with small feature size to reduce errors, especially at sharp corners, due to light scatter at edges. The serifs and notches may be features tailored to be below the resolution of the microfabrication conditions, especially at small wavelength imaging radiation. While serifs and notches may be machined on masks having large features (such as at about 2 mm), the ability to produce serifs for smaller feature sizes may be difficult. A system using demagnification optics may use a first mask with about 2 mm feature size, in which serifs have been machined, to produce target masks incorporating smaller serifs that may otherwise be difficult to manufacture. It may be noted that under the conditions of this first demagnification step, the serifs may still be resolvable structures due to their sizes. The target masks, having the reduced geometry incorporating the serifs and notches, may be used subsequently to produce smaller features on a target. The smaller serifs incorporated into the target masks may then be able to reduce the fringing effects at corner features to produce more accurate target geometries.

### Example 7

### Method of Using Multiple First Masks

The feature sizes of the first microfabrication mask may be restricted due to the resolution of the machining process. As an example, features having about 2 mm size may be the smallest size available for some initial microfabrication processes. Multiple masks may be initially machined with identical features offset by some amount such as 1 mm. The multiple first masks may then be incorporated together in a fixture to secure them during laser illumination. As a result, a 1 mm feature image may be produced and demagnified for presentation to the target.

### Example 8

### Method of Fabricating “Gray-Scale” Masks

For masks used to produce small feature sizes, small wavelength radiation may be used to obtain the required feature resolution on a target. At smaller feature sizes, fringing effects may occur at the edges of the mask features, thus leading to edge blurring at the target. One method to reduce the fringing effects may be to use phase-shifting masks, in which light phase interference may reduce edge scatter from the mask. In one method, a mask may be produced in which the mask base material (such as polyethylene terephthalate) may not be completely ablated, but may be only partially removed. The difference in mask material thickness may thereby cause phase interference of the image produced by the mask. Such interference may function to sharpen the edges of the image produced by the mask and demagnified on the target.

A phase shifting mask may be produced by exposing a target mask to radiation that does not completely ablate the target material at some locations, while mostly ablating the material at others. This effect may be produced by moving the first mask in some direction or directions during the target exposure time, thereby exposing some parts of the target to more energy than other parts. A phase shift mask with small features may thereby be produced by moving the first mask while demagnifying the image at the target.

### Example 9

### Method of Fabricating Masks Comprising Phase Change Material

Phase change materials are those that can change some of their properties under certain types of stimuli, for example temperature change or exposure to radiation. For example, VO₂ undergoes a thermochromic phase transition between a transparent semiconductor and an opaque conductor at about 68° C. The transition can occur as fast as about 0.1 picoseconds (psec). Another example of a phase change material may be a dye that may be light absorbent or opaque under one set of conditions, but may be rendered transparent due to photobleaching when illuminated by light having sufficient power. For example, fluorescein in a film matrix may be bleached after being exposed to high power light of around 488 nm for about 3 milliseconds (msec).

A target may incorporate such phase change material around the area on which the reduced image is presented. Thereafter, the target may be used as a second mask. In one example, a polymer film mask may incorporate VO₂ in areas surrounding the features to be demagnified. The mask may be maintained at a temperature below the thermochromic phase transition point during part of the microfabrication process, and then maintained at a temperature above the phase transition for the remaining fabrication. The result may be a target having some features possessing a shallow depth due to exposure to light only during the low temperature fabrication step (the VO₂ being transparent under that temperature condition). Mask features not incorporating the VO₂ may result in some target areas receiving the light irradiation during the entire exposure process. Small featured masks having a variety of feature depths may be fabricated using demagnification optics on images produced by masks incorporating phase change materials.

### Example 10

### Method of Fabricating Deformable/Self-Regulating Masks

A single microfabrication mask may be used repeatedly to produce a number of targets having the same set of features. However, it is understood that a mask subjected to sufficiently high powered energy may absorb some amount of the energy, resulting in thermal stress to the mask. This may be an important issue especially for masks incorporating small features fabricated using demagnification optics as disclosed above. A method of addressing the issue of thermal warping of such a mask may be to pre-stress the mask in a manner that may compensate for deformation due to thermal warping during use. The thin target film may first be patterned with a fine grid. Thereafter, the target may be exposed to the UV radiation of the demagnified image The grid previously patterned on the film may then be imaged and compared to the original grid. Heat may then be applied to the reduce-image target in a manner to compensate for any distortion caused by the patterning process. As a result, the mask produced by the demagnification process can be corrected for thermal aberrations during use.

### Example 11

### Method of Fabricating Masks Comprising Shape Memory Materials

Shape memory materials are materials that may be deformed under one set of conditions, but may return essentially unchanged to their original shape under a second set of conditions. Nickel-titanium alloys (such as Nitinol) may possess this property as well as some polymers such as polynorbornene and poly ethylene terephthalate (PET). A shape memory material such as PET may be stretched uniformly to serve as a target for microfabrication processing using demagnification optics. After the features have been fabricated in the shape memory target, the target may then be subjected to conditions in which it may change back to its original size (shrink). In this manner, the features previously fabricated on the target to be reduced even further due to the change in the size of the target. The target may then be used as a mask in a second iteration of demagnification optics-based microfabrication of either a second mask or a final target. It is believed that the use of such shape memory materials, in addition to the demagnification optics, may lead to a further reduction in target mask feature size by about a factor of three.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated in this disclosure, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, or compositions, which can, of course, vary. It is also to be understood that the terminology used in this disclosure is for the purpose of describing particular embodiments only, and is not intended to be limiting.

With respect to the use of substantially any plural and/or singular terms in this disclosure, those having skill in the art can translate from the plural to the singular and/or from the singular to the plural as is appropriate to the context and/or application. The various singular/plural permutations may be expressly set forth in this disclosure for sake of clarity.

It will be understood by those within the art that, in general, terms used in this disclosure, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

As will be understood by one skilled in the art, for any and all purposes, such as in terms of providing a written description, all ranges disclosed in this disclosure also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed in this disclosure can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member.

From the foregoing, it will be appreciated that various embodiments of the present disclosure have been described for purposes of illustration, and that various modifications may be made without departing from the scope and spirit of the present disclosure. Accordingly, the various embodiments disclosed are not intended to be limiting, with the true scope and spirit being indicated by the following claims.

1. A method of dry process fabrication of a binary laser microfabrication mask, the method comprising:
providing a laser radiation output;
providing a first laser microfabrication mask having a first side and a second side;
focusing the laser radiation output on the first side of the first laser microfabrication mask, thereby producing a mask image emitted from the second side of the first laser microfabrication mask;
providing a first demagnification optics system having a focal length to receive the mask image, wherein the demagnification optics system is configured to emit a demagnified image;
mounting a target in a frame;
exposing the target to the demagnified image, the target having at least a first side and a second side; wherein an object distance comprises an optical distance from the first laser microfabrication mask to the first demagnifying optics system, an image distance comprises an optical distance from the first demagnifying optics system to the target, a demagnification ratio comprises the object distance divided by the image distance, and the demagnification ratio is greater than 1.0; and
coating at least one of the first side and the second side of the target with a metal film, thereby forming the binary laser microfabrication mask.

2.-8. (canceled)

9. The method of claim 1, wherein providing a laser radiation output comprises providing a laser ultraviolet (UV) radiation output.

10. The method of claim 1, wherein providing a laser radiation output comprises providing a laser radiation output that is pulsed, continuous, or both pulsed and continuous.

11. The method of claim 1, wherein providing a laser radiation output comprises providing a pulsed laser radiation output having a pulse width of about 1 ps to about 1 μs.

12.-22. (canceled)

23. The method of claim 1, wherein providing the first laser microfabrication mask comprises fabricating the first laser microfabrication mask using at least in part a demagnification optics system.

24.-25. (canceled)

26. The method of claim 1, wherein the demagnification ratio is about 2 to about 25.

27.-30. (canceled)

31. The method of claim 1, wherein coating at least one of the first side and the second side of the target comprises coating at least one of the first side and the second side of the target with a plurality of layers.

32.-35. (canceled)

36. The method of claim 1, wherein exposing a target to the demagnified image comprises:
mounting the target on a movable stage;
exposing a first area of the target to the demagnified image;
providing a command to at least one movable stage actuator controller configured to control at least one movable stage actuator in operative connection with the movable stage, thereby causing the actuator to move the stage in a direction;
exposing at least a second area of the target to the demagnified image,
wherein exposing a first area of the target and exposing at least a second area of the target results in a restructuring of the target by at least one of photochemical modification, ablation, and physiothermal modification.

37.-39. (canceled)

40. The method of claim 36, wherein providing a command to at least one movable stage actuator controller comprises at least one of:
automatically sending a command from a programmed computer to the at least one movable stage actuator controller;
sending a command to the at least one movable stage actuator controller via a human interface device; and
sending a command via the human interface device to the computer programmed to send a command to the at least one movable stage actuator controller.

41. The method of claim 1, wherein the binary mask comprises at least one feature, the feature having a size of about 2 μm to about 500 μm.

42.-43. (canceled)

44. The method of claim 1, wherein exposing the target to the demagnified image comprises exposing the target to the demagnified image for a period of time based on at least one of a fixed period of time, a period of time based on a material comprising the target, a period of time based on a thickness of the target, a period of time based on a feature size, and a period of time based on a measurement related to the laser radiation output.

45. The method of claim 1, further comprising:
placing a dichroic mirror in an optical path between the first laser microfabrication mask and the target, thereby forming a mirror image; and
configuring a camera having a camera output to image the mirror image.

46. The method of claim 45, wherein exposing a target to the demagnified image comprises exposing the target to the demagnified image for a period of time based on the camera output.

47. The method of claim 45, wherein exposing a target to the demagnified image comprises:
mounting the target on a movable stage;
moving the movable stage to a position based on the camera output; and
exposing the target to the demagnified image.

48. A system for dry process fabrication of a binary laser microfabrication mask, the system comprising:
a laser radiation output;
a first laser microfabrication mask having a first side and a second side, wherein the first side is optically coupled to the laser radiation output, and the second side is configured to emit a mask image;
a first demagnification optics system having a focal length configured to receive the mask image and to emit a demagnified image;
a target frame configured to hold a target; wherein an object distance comprises an optical distance from the first laser microfabrication mask to the first demagnifying optics system, an image distance comprises an optical distance from the first demagnifying optics system to the target, a demagnification ratio comprises the object distance divided by the image distance, and the demagnification ratio is greater than 1.0; and
a movable stage configured to receive the target frame, wherein the movable stage is movable in one or more of a horizontal direction and a vertical direction.

49.-51. (canceled)

52. The system of claim 48, further comprising at least one laser radiation focusing element configured to receive the laser radiation output.

53.-54. (canceled)

55. The system of claim 48, wherein the laser radiation output comprises radiation having a wavelength of about 150 nm to about 1200 nm.

56.-62. (canceled)

63. The system of claim 48, further comprising a laser radiation output controller.

64. The system of claim 48, wherein the laser radiation output has a continuous irradiance less than or equal to about 10 W/cm².

65.-66. (canceled)

67. The system of claim 48, wherein the first laser microfabrication mask comprises at least one of a metal sheet and a metalized polymer film.

68.-70. (canceled)

71. The system of claim 48, wherein the first laser microfabrication mask comprises laser microfabrication mask fabricated by a laser microfabrication process comprising a second demagnification optics system.

72.-73. (canceled)

74. The system of claim 48, wherein the demagnification ratio is about 2 to about 25.

75.-76. (canceled)

77. The system of claim 48, wherein the target comprises at least one of polyimide, polythene, polytetrafluoroethylene, polyethylene terephthalate, aluminum, stainless steel, copper or combinations thereof.

78.-83. (canceled)

84. The system of claim 48, further comprising:
at least one movable stage actuator configured to move the movable stage;
at least one movable stage actuator controller;
at least one programmed computer in data communication with the at least one movable stage actuator controller;
at least one human interface device in data communication with the at least one movable stage actuator controller; and
at least one human interface device in data communication with a computer in data communication with the at least one movable stage actuator controller.

85.-90. (canceled)

91. The method of claim 1, further comprising controlling a period of time during which the radiation output is focused on the first side of the first laser microfabrication mask.

92.-93. (canceled)

94. The system of claim 48, further comprising:
a dichroic mirror placed in an optical path between the first laser microfabrication mask and the target, thereby forming a mirror image; and
a camera having a camera output configured to receive the mirror image.

95.-96. (canceled)
